(19) United States
(12) Patent Application Publication
(10) Pub. No.: US 2026/0086638 A1
(43) Pub. Date: Mar. 26, 2026

(54) DETECTING PARASITIC LEAKAGE OF ELECTRODES IN A SENSING SYSTEM

(71) Applicant: Apple Inc., Cupertino, CA (US)

(72) Inventors: Sung H Kim, Mountain View, CA (US); Rishika Agarwala, Cupertino, CA (US); Joshua Mitchell, Stanford, CA (US); Myles Y. Lam, San Francisco, CA (US); Seulki Lee, Sunnyvale, CA (US); Thao T. Ngo, Morgan Hill, CA (US); Chia-Yeh Lee, San Jose, CA (US); Hyunsoo Ha, Campbell, CA (US); Muhammad Ahmadi, Santa Clara, CA (US); Justin S. Shi, Santa Clara, CA (US)

(21) Appl. No.: 19/295,528

(22) Filed: Aug. 8, 2025

Related U.S. Application Data
(60) Provisional application No. 63/698,548, filed on Sep. 24, 2024.

(51) Int. Cl. G06F 3/01; G01R 31/28; G06F 1/16

(52) U.S. Cl. CPC G06F 3/015; G01R 31/2829; G06F 1/163

(57) ABSTRACT

Embodiments are directed to systems and methods for using a contact signal to identify and account for parasitic leakage during operation of an electronic device. A test signal is applied to a set of electrodes to generate a contact signal that may be measured by processing circuitry of the device. The presence of extraneous materials between an electrode and a conductive, circuit-connected housing of the electronic device may reduce the amplitude of the contact signal. The device may perform a biological signal measurement based on whether the contact signal level is above a first threshold, thereby indicating an acceptable level of parasitic leakage. The device may also compare the contact signal level to a second threshold that indicates sufficient contact between the user and the electrodes. If the contact signal level is above the first threshold and below the second threshold, the device may perform a biological measurement.

### CROSS-REFERENCE TO RELATED APPLICATIONS

This application claims the benefit under 35 U.S.C. § 119 (e) of U.S. Provisional Patent Application No. 63/698,548, filed Sep. 24, 2024, the contents of which are incorporated herein by reference as if fully disclosed herein.

### TECHNICAL FIELD

The described embodiments relate generally to systems and methods for detecting parasitic leakage of one or more electrodes of an electronic device, and performing a biological signal measurement based on whether parasitic leakage is detected.

### BACKGROUND

Many electronic devices may include electrodes that are used to acquire biological signals from a user. As an example, a smartwatch may include a set of electrodes used to measure an electrocardiogramaignal or other type of biological signal from the user. Measuring such a biological signal may require a baseline quality of contact between the skin of the user and two or more of the device electrodes, and may additionally require that the electrodes be relatively free of extraneous materials (e.g., moisturizers, sunscreen, or the like). In some situations, the extraneous materials may be present on one or more surfaces of the electronic device and may form one or more conductive pathways between one or more of the device electrodes and a conductive housing (or other structure) of the device, which may cause parasitic leakage during operation of the electronic device. In situations where the conductive housing is electrically connected to a circuit reference (e.g., a circuit ground) or other circuit node, this parasitic leakage may degrade the amplitude of the measured biological signal, may introduce additional noise to the biological signal, and/or may affect other aspects of the measurement. Accordingly, it may be desirable to identify and account for parasitic leakage during operation of an electronic device.

### SUMMARY

Embodiments described herein are directed to systems and methods for detecting buildup of extraneous material on a set of electrodes of an electronic device. Some embodiments are directed to a device comprising a signal electrode, reference electrode, signal generator configured to apply a test signal to the signal electrode, and processing circuitry. The processing circuitry is configured to perform a biological signal measurement using the signal and reference electrode. In some variations, the device comprises a housing, and the signal and reference electrode are positioned on a common side of the housing.

The processing circuitry is further configured to measure a contact signal associated with the biological signal measurement, wherein the contact signal level of the contact signal is measured between the signal electrode and reference electrode while the test signal is applied to the signal electrode. The processing circuitry compares the contact signal level to a first threshold and cancels the biological signal measurement when the contact signal level is determined to be below the first threshold.

In some variations, the processing circuitry is further configured to provide a notification to the user when the contact signal level is determined to be below the first threshold. In other variations, canceling the biological signal measurement comprises forgoing commencement of the biological signal measurement.

In some instances, the processing circuitry is further configured to compare the contact signal level to a second threshold and cancel the biological signal measurement when the contact signal level is determined to be above the second threshold.

In some variations, the processing circuitry is configured to measure the contact signal prior to commencing the biological signal measurement. In other variations, the processing circuitry is configured to measure the contact signal during performance of the biological signal measurement. In such a variation, canceling the biological signal measurement comprises terminating performance of the biological signal measurement. In further variations, the processing circuitry is configured to measure the contact signal continuously during the performance of the biological signal measurement.

Embodiments are also directed to a method for detecting electrode parasitic leakage, comprising applying a test signal to a signal electrode and measuring a contact signal associated with a biological signal. The contact signal level of the contact signal is measured between the signal electrode and the reference electrode with the test signal is applied to the signal electrode. The method further comprises determining that the contact signal level is below a first threshold, and in response to determining that the contact signal level is below the first threshold, canceling the biological signal measurement. In some variations, the method further comprises providing a notification to a user in response to determining that the contact signal level is below the first threshold.

In some instances, canceling the biological signal measurement comprises forgoing commencement of the biological signal measurement. In other instances, measuring the contact signal comprises measuring the contact signal during performance of the biological signal measurement, and canceling the biological signal measurement comprises terminating performance of the biological signal measurement.

In some variations, the method further comprises comparing the contact signal level to a second threshold and canceling the biological signal measurement when the contact signal level is above the second threshold.

In some instances, determining that the contact signal level is below the first threshold includes calculating an average contact signal level and comparing the calculated average contact signal level to the first threshold.

Embodiments are also directed to a method comprising applying a test signal to a signal electrode and measuring a contact signal associated with the signal electrode and a reference electrode while the test signal is applied to the signal electrode. In some instances, the method comprises applying a sinusoidal test signal.

The method further comprises determining that a signal level of the contact signal is below a first threshold and, in response, providing a notification to a user. In some variations, the method further comprises canceling a biological signal measurement in response to determining that the signal level of the contact signal is below the first threshold. In such variations, measuring the contact signal comprises measuring the contact signal during performance of the biological signal measurement.

In other variations, determining that the contact signal level is below the first threshold includes calculating an average contact signal level and comparing the calculated average contact signal level to the first threshold.

In addition to the exemplary aspects and embodiments described above, further aspects and embodiments will become apparent by reference to the drawings and by study of the following description.

### BRIEF DESCRIPTION OF THE DRAWINGS

To easily identify the discussion of any particular element or act, the most significant digit or digits in a reference number refer to the figure number in which that element is first introduced.

FIG. 1 depicts a block diagram of an example electronic device as described herein.

FIGS. 2A-2B depict front and rear views, respectively, of an example electronic device as described herein.

FIG. 3 depicts a schematic diagram of an example electrode interface and processing circuitry that can be used to determine parasitic leakage of one or more electrodes.

FIG. 4 depicts an example method for determining whether to perform a biological signal measurement based on a determined contact signal level.

FIG. 5 depicts another example method for determining whether to perform a biological signal measurement based on a determined contact signal level.

The use of cross-hatching or shading in the accompanying figures is generally provided to clarify the boundaries between adjacent elements and also to facilitate legibility of the figures. Accordingly, neither the presence nor the absence of cross-hatching or shading conveys or indicates any preference or requirement for particular materials, material properties, element proportions, element dimensions, commonalities of similarly illustrated elements, or any other characteristic, attribute, or property for any element illustrated in the accompanying figures.

Additionally, it should be understood that the proportions and dimensions (either relative or absolute) of the various features and elements (and collections and groupings thereof) and the boundaries, separations, and positional relationships presented therebetween, are provided in the accompanying figures merely to facilitate an understanding of the various embodiments described herein and, accordingly, may not necessarily be presented or illustrated to scale, and are not intended to indicate any preference or requirement for an illustrated embodiment to the exclusion of embodiments described with reference thereto.

### DETAILED DESCRIPTION

Reference will now be made in detail to representative embodiments illustrated in the accompanying drawings. It should be understood that the following descriptions are not intended to limit the embodiments to one preferred embodiment. To the contrary, it is intended to cover alternatives, modifications, and equivalents as can be included within the spirit and scope of the described embodiments as defined by the appended claims.

An increasing number of electronic devices include a plurality of electrodes that can be used to perform one or more biological signal measurements, during which the electrodes are used to measure a biological signal from a user. For example, a variety of smartwatches include a set of electrodes for acquiring biological signals associated with ECG, electromyography (EMG), and/or other biological signals associated with other types of electrical activity in the body of the user. In some cases, the device may analyze the ECG, EMG, and/or other signals to evaluate the health or wellness of the user (e.g., evaluate the ECG signal for heart conditions), perform a task or function (e.g., use the EMG signal to control a device feature), and/or for other purposes. Analysis of the biological signals may be dependent on the signal quality of the acquired biological signals. For example, biological signals that are noisy, include significant artifacts (e.g., motion artifacts), have low amplitude, or otherwise have poor signal quality may hamper analysis of the biological signals.

One aspect of the measurement of biological signals that may affect signal quality is the presence of extraneous materials on one or more surfaces of the device. These extraneous materials may include solid or liquid contaminants with varying levels of conductivity. Examples of contaminants can include sweat, water, sunscreen, lotion, solid foreign matter, and/or other types of contaminants. In some situations, extraneous materials may form one or more conductive pathways between one or more device electrodes and a conductive structure of the device that is electrically connected to a circuit node of a device circuit. For example, the device may include a type of conductive housing (e.g., a steel housing) that is electrically connected within the device to a circuit reference (e.g., a circuit ground), or other circuit node of a device circuit. In other examples, the device may include other conductive structures (e.g., a button, a crown, etc.) that may be electrically connected to a circuit node. A conductive pathway between one or more electrodes and one or more of these conductive (circuit-connected) structures may alternatively be referred to as a “parasitic leakage pathway.”

When one or more parasitic leakage pathways are present, the quality of the measured biological signal may be negatively affected in any of several ways. For example, each parasitic leakage pathway may result in a low-impedance connection from one or more of the electrodes to a circuit ground. This parasitic leakage experienced by the electrodes may negatively impact the measured biological signal, such as by causing attenuation of the biological signal, increasing measurement noise, or the like.

Embodiments disclosed herein are directed to systems and methods that use a contact signal to identify the presence of parasitic leakage pathways. The electrodes may include electrodes intended for placement in contact with one or more regions of a user (e.g., a user's wrist, one or more fingers, and/or other portions of the user's body). The device applies a test signal to a signal electrode and measures the resulting contact signal. The signal level of the contact signal may provide an indication of, or may represent, parasitic leakage and/or the quality of contact between the skin and the electrode(s).

As an example, the device may analyze the measured contact signal and determine whether the contact signal level is below a first threshold. The first threshold may represent a maximum tolerable level of attenuation caused by the parasitic leakage. When the contact signal is attenuated to a level below the first threshold, the device may no longer support a biological signal measurement. Accordingly, in some embodiments, the device may cancel the biological signal measurement if the contact signal level falls below the first threshold.

Another aspect of the measurement of biological signals that may affect signal quality is the degree or quality of contact between one or more of the electrodes and the skin of the user. For example, poor contact between one or more electrodes and the skin may reduce the amplitude of biological signals, increase noise, or otherwise affect biological signal quality. Factors that may affect the quality of contact between the electrode and the user's skin may include the contact surface area between the electrode and skin, the amount of force (or pressure) applied between the skin and electrode, the moisture content of the user's skin, the presence of contaminants as described herein, other types of foreign matter between the electrode and skin (e.g., solid or liquid foreign matter), and/or other factors.

The device may also determine whether the contact signal level is above a second threshold that is higher than the first threshold. The second threshold may represent a minimum level of electrode-skin contact needed to support the biological signal measurement. In some embodiments, the minimum level of electrode-skin contact may be represented by an electrode-skin contact impedance, which corresponds to the contact signal level. For instance, when the electrodes are not in contact with the skin (e.g., when the smartwatch is not being worn by the user) or the electrodes are in poor contact with the skin, the electrode-skin impedance may be very high (e.g., may approximate an open circuit). Accordingly, the contact signal level may be very large. In some embodiments, the device may cancel the biological signal measurement if the contact signal level exceeds the second threshold.

Accordingly, in some instances, the electronic devices and methods may only perform a biological signal measurement if the contact signal level is between the first threshold and the second threshold. In these instances, the contact signal level may indicate that the parasitic leakage and skin contact are both at acceptable levels.

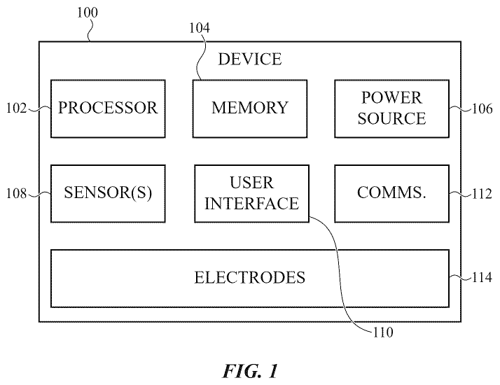

These and other embodiments are discussed below with reference to FIGS. 1-5. However, those skilled in the art will readily appreciate that the detailed description given herein with respect to these figures is for explanatory purposes only and should not be construed as limiting.

FIG. 1 depicts a block diagram of an example electronic device 100 that may measure a contact signal and use a contact signal level to identify parasitic leakage. The device 100 can include a processor 102, memory 104, a power source 106, one or more sensors 108, a user interface 110, a communications unit 112, and a set of electrodes 114.

The processor 102 can control some or all of the operations of the device 100. The processor 102 can communicate, either directly or indirectly, with some or all of the components of the device 100. For example, a system bus or other communication mechanism can provide communication between the processor 102, the memory 104, the power source 106, the one or more sensors 108, the user interface 110, the communications unit 112, and elements associated with the electrodes 114.

The processor 102 can be implemented as any electronic device capable of processing, receiving, or transmitting data or instructions. For example, the processor 102 may include a processor, a microprocessor, a graphics processing unit (GPU), a programmable logic array (PLA), a programmable array logic (PAL), a generic array logic (GAL), a complex programmable logic device (CPLD), an application-specific integrated circuit (ASIC), a field-programmable gate array (FPGA), or any other programmable logic device (PLD) configurable to execute an operating system and applications of device 100, as well as to facilitate acquisition and processing of signals as described herein. The term “processor,” as used herein, is meant to encompass a single processor or processing unit, multiple processors, multiple processing units, or other suitable computing element or elements.

It should be noted that the components of the device 100 can be controlled by multiple processors. For example, select components of the device 100 (e.g., a sensor 108) may be controlled by a first processor and other components of the device 100 (e.g., the communications unit 112) may be controlled by a second processor, where the first and second processors may or may not be in communication with each other.

The memory 104 can store electronic data that can be used by the electronic device 100. For example, the memory 104 can store electrical data or content such as, for example, measured electrical signals, audio and video files, documents and applications, device settings and user preferences, timing signals, control signals, and data structures or databases. The memory 104 can include one or more non-transitory computer-readable storage devices, for storing computer-executable instructions, which, when executed by one or more computer processors 102, for example, can cause the computer processors to perform the techniques that are described herein. A computer-readable storage device can be any medium that can tangibly contain or store computer-executable instructions for use by or in connection with the instruction execution system, apparatus, or device. In some examples, the storage device is a transitory computer-readable storage medium. In some examples, the storage device is a non-transitory computer-readable storage medium. The non-transitory computer-readable storage device can include, but is not limited to, magnetic, optical, and/or semiconductor storages. Examples of such storage include magnetic disks, optical discs based on CD, DVD, or Blu-ray technologies, as well as persistent solid-state memory such as flash, solid-state drives, and the like.

The power source 106 can be implemented with any device capable of providing energy to the device 100. For example, the power source 106 may be one or more batteries or rechargeable batteries. The power source 106 may include battery charging components within the device 100, which may receive power, charge the battery, and/or provide direct power to operate the device 100 regardless of the battery's state of charge (e.g., bypassing the battery of the device 100). In some cases, the battery charging components may include a coil such that the device 100 may receive power wirelessly (e.g., via inductive power transfer). The device 100 may include a magnet, such as a permanent magnet, that magnetically couples to a magnet (e.g., a permanent magnet, electromagnet) or magnetic material (e.g., a ferromagnetic material such as iron, steel, or the like) in a charging dock (e.g., to facilitate wireless charging of the device 100).

The device 100 also includes one or more sensors 108. The sensor(s) 108 can be configured to sense one or more type of parameters, such as but not limited to, electrical signals, pressure, sound, light, touch, heat, movement, relative motion, biometric data (e.g., physiological parameters), and so on. For example, the sensor(s) 108 may include one or more pressure sensors, auditory sensors, heat sensors, position sensors, light or optical sensors, accelerometers, pressure transducers, gyroscopes, magnetometers, GPS sensors, health monitoring sensors, and so on. The health monitoring sensors may include an optical or other type of heart rate sensor, an ECG, an EMG, and/or other types of health sensors. Additionally, the one or more sensors 108 can utilize any suitable sensing technology, including, but not limited to, capacitive, ultrasonic, resistive, optical, ultrasound, piezoelectric, and thermal sensing technology.

The sensor(s) 108 may further include analog and/or digital processing circuitry that may be associated with acquiring and/or processing signals associated with the above-described sensors and/or sensing technologies. In non-limiting examples, such processing circuitry may include amplifiers, signal filters, analog-to-digital converters (ADCs), demodulators, memory elements, and/or other types of components or elements. The sensor(s) 108 may also include additional circuitry used to configure sensor measurements. For example, the sensor(s) 108 may include a set of one or more switches, multiplexers, signal generators, and/or other circuitry associated with acquiring sensor measurements. In a health sensor example, one or more circuit elements of the sensor(s) 108 may be coupled to one or more of the electrodes 114, such as with an ECG sensor, EMG sensor, or the like. When one or more circuit elements of the sensor(s) 108 are coupled to one or more electrodes of the set of electrodes 114, those electrodes may be considered part of that sensor. In some variations, the set of electrodes 114 (or a portion thereof) may be part of different sensors at different times. For instance, a device may include two sensors (e.g., an ECG sensor and an EMG sensor) that use the same set or subset of electrodes at different times (e.g., the ECG sensor may use a set of electrodes to perform an ECG measurement at a first time and the EMG sensor may use the same set of electrodes at other times to perform an EMG measurement). Circuit elements associated with these sensors may also be associated with acquiring/processing a biological signal from the user, and/or with determining contact between the skin of the user and one or more of the electrodes 114, as described herein.

The device 100 includes a user interface 110, which may include a type of graphical display. The display may be implemented as a liquid-crystal display (LCD), organic light-emitting diode (OLED) display, light-emitting diode (LED) display, or the like. If the display is an LCD (or other type of display technology), the display may also include a backlight component that can be controlled to provide variable levels of display brightness. If the display is an OLED or LED type display (or other type of display technology), the brightness of the display may be controlled by modifying the electrical signals that are provided to display elements. In some examples, the display may be a type of touch-sensitive display (e.g., a capacitive touch display) that allows a user to provide input to the device 100 via touch-based interaction with the display screen.

The user interface 110 may include other types of user interface elements. For example, the user interface can include one or more buttons, dials, switches, knobs, levers, and/or other types of inputs. In some examples, the user interface 110 may include a type of rotatable input device or a depressible and rotatable input device (such as the rotatable and depressible crown associated with a smartwatch). In additional examples, the user interface 110 may include one or more cameras, one or more microphones, one or more speakers, a keyboard, and/or other types of user interface elements.

In further examples, the user interface 110 may provide graphical user interface (GUI) elements on the display of the device. For example, the user interface 110 may provide virtual buttons (e.g., a graphical user interface “home” button), slide controls, and/or any of a variety of other types of virtual user inputs and/or controls on the display of the device 100. The user interface 110 may further provide graphical output, such as text, lists, symbols, signals, waveforms, photographs, videos and/or other graphics, to the display of the device 100. In still further examples, the user interface 110 may provide a GUI to a display of the device 100, where one or more graphical objects of the GUI display information collected from or derived from one or more of the sensor(s) 108. For example, the user interface 110 may output information related to a measurement performed by a particular sensor, such as the type of measurement performed, the status of the measurement (e.g., “in progress” or “completed”), the results of the measurement, or so on.

The communications unit 112 can transmit data to, and/or receive data from, another electronic device. The communications unit 112 can transmit/receive electronic signals via a communications network, such as a wireless and/or wired network connection. Examples of wireless and wired network connections include, but are not limited to, NFC, RF, cellular, Wi-Fi, Bluetooth, IR, and Ethernet connections. The communications unit 112 may further include one or more ports and/or connectors for establishing wired connection with another device or devices.

The device 100 includes a set of two or more electrodes 114. The electrodes 114 may be positioned on an exterior, user-accessible surface of the device, such as on a surface of the device housing, on a surface of a user interface element (e.g., a button, a dial, etc.), and/or on other surfaces of the device 100. The electrodes 114 may be fabricated from any of a variety of suitable materials, which may provide a range of conductivity values. For example, the electrodes 114 may be a type of metal, glass, ceramic, composite, or other type of material. In some examples, all of the electrodes 114 may be the same type of material, while in other examples one subset of one or more of the electrodes 114 may be comprised of a different material than another subset or subsets of the electrodes 114.

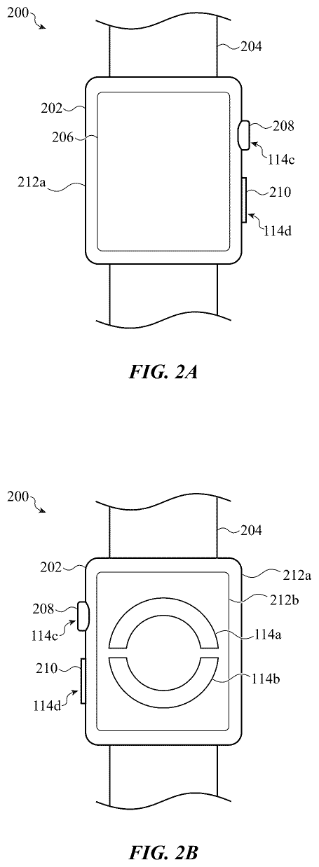

In general, the set of electrodes includes multiple electrodes. For instance, the device 100 may include three or more electrodes, such as depicted with respect to FIGS. 2A-2B. Depending on the type of sensor and the measurement being performed, a given electrode of the set of electrodes may be configured as a sensing electrode or as a reference electrode. In some variations, a reference electrode may be used to establish connection between the user and a reference point of the associated sensor processing circuitry (e.g., a circuit ground or other reference point), and a sensing electrode may measure a potential relative to the reference point. In certain variations, the device 100 may not include a reference electrode, and each subset of electrodes may be comprised entirely of sensing electrodes.

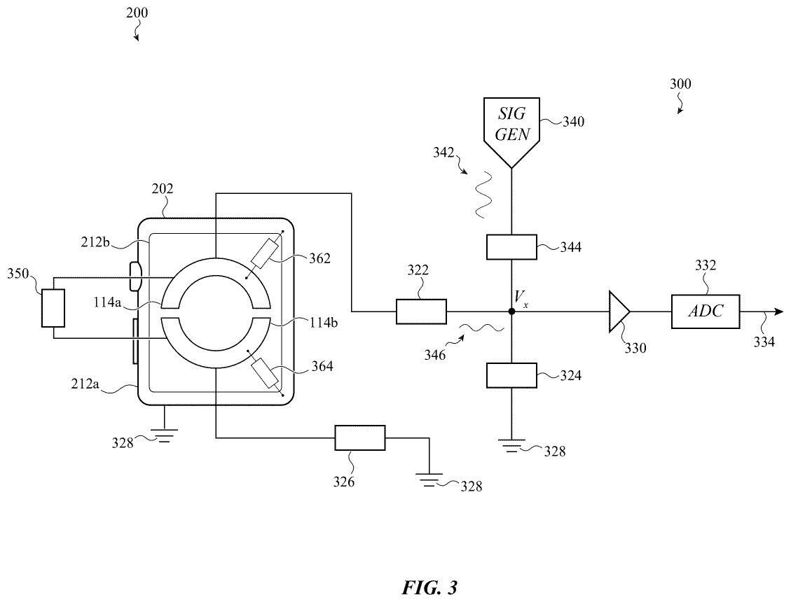

As described herein, processing circuitry and/or other circuitry associated with the acquisition and processing of signals acquired from one or more of the electrodes 114 may be part of processor 102, sensor(s) 108, electrodes 114, and/or other elements of device 100. Exemplary circuit elements of device 100 are depicted in FIG. 3 and described herein.

FIG. 2A shows a front view of an example smartwatch 200 and FIG. 2B shows a rear view of the example smartwatch 200, which may use a contact signal to identify parasitic leakage, as described herein. The smartwatch 200 may include the elements described above with respect to device 100 of FIG. 1, and may be capable of performing any or all the functions of device 100 described herein. The smartwatch 200 is merely one example embodiment of an electronic device, and the concepts discussed herein may apply equally or by analogy to other electronic devices, including, smart band, smart ring, mobile phones (e.g., smartphones), tablet computers, notebook computers, head-mounted display devices, headphones, earbuds, digital media players (e.g., mp3 players), or the like.

The smartwatch 200 includes a housing 202 and a band 204 coupled thereto. The housing 202 may at least partially define an internal volume in which components of the smartwatch 200 may be positioned. The housing 202 may also define one or more exterior surfaces of the device, such as all or a portion of one or more side surfaces, a rear surface, a front surface, and the like. Further, the housing 202 may include one or more electrically conductive regions, such as conductive region 212a, and one or more nonconductive regions, such as non-conductive region 212b. In some embodiments, the conductive region 212a may be formed from one or more electrically conductive materials, such as a type of metal (e.g., aluminum, steel, titanium, or the like). The non-conductive region 212b formed from one or more electrically insulating materials, such as glass (e.g., a type of crystal), plastic, composite, or other types of non-conductive material. The electrodes 114a-114b may be positioned in the non-conductive region 212b, such that the non-conductive region 212b separates each of the electrodes 114a-114b from electrodes 114c-114d, and separates the electrodes 114a-114b from the conductive region 212a.

In further embodiments, a portion of the rear surface of the housing 202 (e.g., the non-conductive region 212b) may include one or more windows (not depicted), which may allow light to pass through a portion of the rear surface. The one or more windows may be part of an optical sensing system, which may be part of a health sensor or other type of sensor(s) (e.g., sensor(s) 108). For instance, the sensor(s) may be used to determine biometric information of a user, such as heart rate, blood oxygen concentrations, and the like, as well as information such as distance from the smartwatch to an object. For example, the sensor(s) may provide information that may be used to help determine whether the user is wearing a smartwatch. The portion(s) of the rear surface associated with the one or more windows may comprise light transmissive materials, different than the material of the rear surface (e.g., different than the material of the non-conductive region 212b). The light transmissive materials may permit light (e.g., infrared (IR), visible light, etc.) associated with the operation of the sensor(s) to pass through the rear surface.

The smartwatch 200 further includes user interface elements, such as described herein for user interface 110 of FIG. 1. For example, the smartwatch 200 includes display 206, a first input device 208, and a second input device 210. The display 206 may be configured in any manner as described herein. For instance, the display 206 may be a type of touch-sensitive display capable of receiving input via touch interaction from the user. The smartwatch 200 may display the output of sensor measurements on the display 206, such as data or information associated with a measurement performed by a sensor, as described herein (e.g., an ECG measurement, EMG measurement, electrode-skin contact measurement, etc.).

The first input device 208 may have a cap, crown, protruding portion, or component(s) or feature(s) positioned along a side surface of the housing 202. At least a portion of the first input device 208 (such as a crown body) may protrude from, or otherwise be located outside, the housing 202, and may define a generally circular shape or circular exterior surface. The exterior surface of the first input device 208 may be textured, knurled, grooved, or otherwise have features that may improve the tactile feel of the first input device 208 and/or facilitate rotation sensing.

The first input device 208 may facilitate a variety of potential interactions. For example, the first input device 208 may be rotated by a user (e.g., the crown may receive rotational inputs). Rotational inputs of the first input device 208 may zoom, scroll, rotate, or otherwise manipulate a user interface or other object displayed on the display 206 among other possible functions. The first input device 208 may also be translated or pressed (e.g., axially) by the user. Translational or axial inputs may select highlighted objects or icons, cause a user interface to return to a previous menu or display, or activate or deactivate functions among other possible functions.

In some cases, the smartwatch 200 may sense touch inputs or gestures applied to the first input device 208, such as a finger sliding along the body of the first input device 208 (which may occur when first input device 208 is configured to not rotate) or a finger touching the body of the first input device 208. In such cases, sliding gestures may cause operations similar to the rotational inputs, and touches on a cap or crown may cause operations similar to the translational inputs. As used herein, rotational inputs include both rotational movements of the first input device 208, as well as sliding inputs that are produced when a user slides a finger or object along the surface of a crown in a manner that resembles a rotation (e.g., where the crown is fixed and/or does not freely rotate).

In additional cases, the first input device 208, or portions thereof, may be connected to a device circuit node as described herein. For example, portions of the first input device 208 may be formed from a conductive material (e.g., steel, aluminum, etc.), and connected to a circuit ground of the device.

The smartwatch 200 may also include other input devices, switches, buttons, or the like. For example, the smartwatch 200 includes a second input device 210, which may be a button. The second input device 210 may be a movable button or a touch-sensitive region of the housing 202. The button may control various aspects of the smartwatch 200. For example, the button may be used to select icons, items, or other objects displayed on the display 206, to activate or deactivate functions (e.g., to silence an alarm or alert), or the like.

In some variations, the second input device 210, or portions thereof, may be connected to a device circuit node as described herein. For example, portions of the second input device 210 may be formed from a conductive material (e.g., steel, aluminum, etc.), and connected to a circuit ground of the device.

The smartwatch 200 is depicted in FIGS. 2A and 2B as including a set of four electrodes 114a-114d (e.g., a first electrode 114a, a second electrode 114b, a third electrode 114c, and a fourth electrode 114d) for acquiring a biological signal from the user. In other examples, the smartwatch 200 (or other device) may include more or fewer electrodes. The electrodes of the set of electrodes 114a-114d may be positioned on any portions of the smartwatch 200 as may be needed to perform measurements using the sensors described herein.

For example, the rear surface of the housing 202 may include one or more electrodes. In the example depicted in FIG. 2B, the rear surface includes two electrodes 114a-114b of the set of electrodes, positioned in the non-conductive region 212b. In some examples, electrodes 114a-114b may be used to make contact with the user's wrist, other portion of the user's arm, or other portion of the user's body. In some examples, electrodes 114a-114b may include more or fewer electrodes than depicted in FIG. 2B. Further, the electrodes 114a-114b may be located on other portions of the rear surface of housing 202, may be shaped differently than depicted, and/or may be positioned and/or oriented on the rear surface of housing 202 according to another arrangement.

In the example depicted in FIGS. 2A and 2B, the smartwatch 200 may include additional electrodes 114c-114d of the set of electrodes, which may be used for making contact with the finger of the user, or with another portion of the user's body. For example, a surface of first input device 208 and/or second input device 210 may include electrodes 114c-114d, respectively. In some variations, the surface of the first input device 208 may include a single electrode (such as depicted), two electrodes, three electrodes, or more. Similarly, the surface of the second input device 210 may include a single electrode (such as depicted), two electrodes, three electrodes, or more.

In some embodiments, the electrodes 114c-114d may be electrically isolated from portions of the first input device 208 and second input device 210, respectively. For instance, as described herein, the first input device 208 may be connected to a circuit node of the device, such as a device circuit ground. The first input device 208 and/or third electrode 114c may be configured to prevent electrical conduction between, such as by the presence of electrical insulating material positioned between the first input device 208 and third electrode 114c. Similarly, the second input device 210 may be connected to a device circuit ground, and the second input device 210 and fourth electrode 114d may be electrically isolated from one another.

The electrodes 114a-114d may be conductively coupled to processing and/or other circuitry within the smartwatch 200, such as described herein (e.g., circuitry associated with processor 102, sensor(s) 108, and/or the electrodes 114a-114d themselves). FIG. 3 depicts a schematic diagram of an example electrode interface and processing circuitry 300 that can be used by smartwatch 200 (or other device) to determine parasitic leakage of one or more electrodes. In the configuration depicted, electrode 114a is configured as a signal electrode, which is connected to a portion of the processing circuitry 300 at node Vx. Electrode 114a is used to measure a biological signal relative to electrode 114b, which is configured as a reference electrode. Electrode 114b provides connection between the user and a circuit reference (e.g., circuit ground 328). The biological signal acquired by the signal electrode 114a is provided to processing circuitry 300 at node Vx, and is measured by the processing circuitry 300, relative to circuit ground 328. As described herein, additional signals may be provided to the processing circuitry 300 at node Vx. For example, in addition to a biological signal, node Vx may include noise, measurement artifacts, and/or other types of signals.

As further depicted in FIG. 3, the conductive region 212a of the smartwatch 200 is electrically connected to the circuit ground 328. In some variations, the conductive region 212a may be connected to another node of the device circuit.

It should be appreciated that in some embodiments, the connection between electrode 114a and node Vx, and between electrode 114b and circuit ground 328, may include additional circuit passive components 322 and 326, respectively. For example, passive components 322 and 326 may include parasitic circuit components, such as circuit trace resistances. In addition, in other embodiments, the passive components 322 and 326 may include circuit components such as resistive, capacitive, and/or inductive circuit components that provide electrical impedance.

In some embodiments, passive components 324 may be present between node Vx and the circuit reference (e.g., circuit ground 328). Passive components 324 may include resistive, capacitive, and/or inductive components. In some examples, passive components 322 and/or 324 may include parasitic components that are inherent to the circuit. For instance, passive components 324 may include circuit trace resistances, capacitances formed between circuit traces and circuit ground 328, and/or other types of parasitic components that may be present.

The processing circuitry 300 may further include a type of amplifier 330. In some embodiments, the amplifier 330 may provide amplification (e.g., signal gain) to the signal present at node Vx (e.g., relative to circuit ground 328), while in other embodiments the amplifier 330 may be configured to provide unity gain (e.g., amplifier 330 may be configured as a buffer amplifier). The amplifier 330 may be configured as a single-stage amplifier (e.g., an appropriately configured single operational amplifier) or may, in some variations, be configured as a multi-stage amplifier. In some instances, the amplifier 330 may be designed to provide very high input impedance, or otherwise provide minimal loading of node Vx, so as to minimize the measurement effects of the amplifier 330 on the signal present at node Vx (e.g., to minimize effects on signal amplitude).

In some variations, amplifier 330 may be configured to provide signal filtering. For example, amplifier 330 may include components that form a low-pass filter, high-pass filter, and/or other type of filter. Additionally or alternatively, the amplifier 330 may include components for performing other types of signal conditioning or processing. In still further variations, the processing circuitry may not include amplifier 330, or may include other types of components in lieu of amplifier 330.

The processing circuit may also include an analog-to-digital converter (ADC) 332 that provides digital output samples 334 of the signal measured at node Vx and output by the amplifier 330. The ADC 332 may be any of a wide variety of ADCs suitable for providing output samples 334. For example, the ADC 332 may be a type of sigma-delta ADC, successive approximation ADC, or other type of ADC. The ADC 332 may include one or more types of output filters, such as a decimation filter and/or other types of filters. Further, the ADC 332 may be configured to provide output samples 334 at a fixed sampling rate (which may be configurable). The output samples 334 may be further processed to determine whether the level of parasitic leakage (if present) is at an acceptable level and that the user is making sufficient contact with the electrodes 114a-114b, as described herein.

When the smartwatch 200 is being worn by the user, electrodes 114a-114b may be in contact with a skin of the user, such as the skin of the user's wrist. As described herein, an impedance exists between each of the electrodes 114a-114b and the user. The impedance may depend at least in part on surface area of contact between each electrode 114a-114b and the skin of the user (or a complete lack of contact), the presence of moisture between each electrode 114a-114b and the user, the skin condition of the user, the type of skin in contact with each electrode 114a-114b (e.g., glabrous or non-glabrous skin), and/or a range of other factors. The electrode-skin impedance for both electrodes 114a-114b is represented as a single user impedance 350.

In some examples, the user impedance 350 may also include a biological signal source that may exist between electrodes 114a-114b. For instance, as described herein, electrodes 114a-114b may be used as part of an EMG sensing system. In such an example, the user impedance may include a biological signal source that represents wrist muscle activity, wrist muscle activation by nervous tissue, and/or other EMG signal sources associated with parts of the hand, wrist, arm, and/or other portions of the body. During a biological signal measurement, the biological signal source included in user impedance 350 may provide a biological signal that may be measured at node Vx.

The processing circuitry 300 is configured to apply a test signal 342 to electrode 114a, and may measure a contact signal from the electrode 114a (at node Vx) while the test signal 342 is being applied. This contact signal may be used to identify parasitic leakage pathways and/or provide an indication of contact quality with a user's skin. To determine whether the user is making a threshold amount of contact with the electrode 114a and/or 114b, the smartwatch 200 includes components for generating and applying a test signal 342. As depicted in FIG. 3, these components may include a signal generator 340, which may be a type of digital-to-analog converter (DAC), or may be another type of component or circuit capable of generating a suitable test signal 342. The test signal 342 is depicted as having a sinusoidal waveform, it should be appreciated that the test signal 342 may have any suitable waveform, such as a triangular waveform, a square waveform, or the like. Further, the test signal 342 may be periodic, with a defined signal frequency, or in some variations may be aperiodic (e.g., a set of one or more pulses applied non-periodically).

The test signal 342 may be coupled to the electrodes 114a-114b via coupling impedance 344. For example, the coupling impedance 344 may be one or more capacitors that capacitively couple the test signal 342 to node Vx, where the test signal 342 may be applied to the electrodes 114a-114b via passive components 322 and 326. The combination of the passive components 322 and 326, and the user impedance 350 forms a voltage divider with the coupling impedance 344. This voltage divider reduces the amplitude of the applied test signal 342, resulting in a contact signal 346 at node Vx that represents at least the impedance combination of the passive components 322 and 326, and the user impedance 350. When the skin of the user is in good contact with the electrodes 114a and 114b, the user impedance 350 is lower, which results in a lower amplitude contact signal 346. Conversely, when the skin of the user is in poor contact with one or both of the electrodes 114a-114b, the user impedance 350 is higher, resulting in a higher amplitude contact signal 346. In situations where the skin of the user is not in contact with either electrode 114a-114b (e.g., user impedance 350 behaves as an open circuit), the contact signal 346 may have very high amplitude, such as near or equal to the amplitude of the test signal 342. Thus, the user impedance 350 affects the amplitude of the contact signal, which may be used to indicate suitable electrode-skin contact, as described herein.

It should further be appreciated that the signal at node Vx includes signal components of the contact signal 346, in addition to signal components of a biological signal, noise, measurement artifact, and/or other signal components that may be measured by the electrodes. The signal at node Vx may serve as an input signal to the processing circuitry, as described herein.

In some situations, the extraneous materials may be present between the skin of the user and a conductive, circuit-connected housing (e.g., housing 202). FIG. 3 depicts examples in which extraneous materials may form one or more conductive pathways between one or both of the electrodes 114a-114b and the housing 202 (e.g., via parasitic leakage 362 and/or 364).

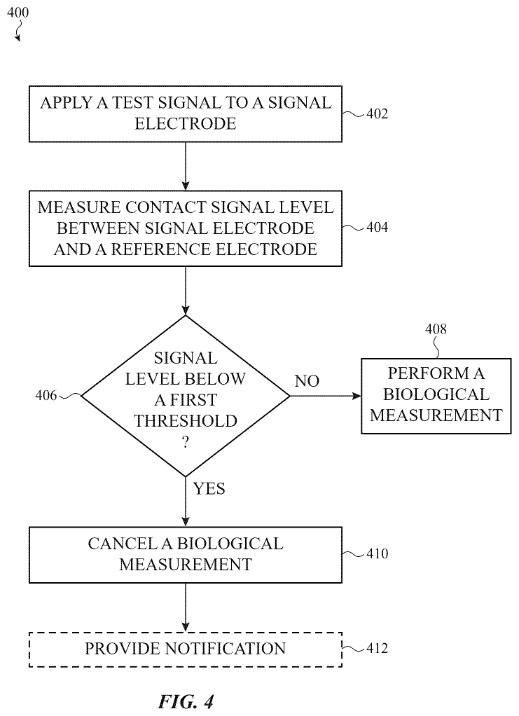

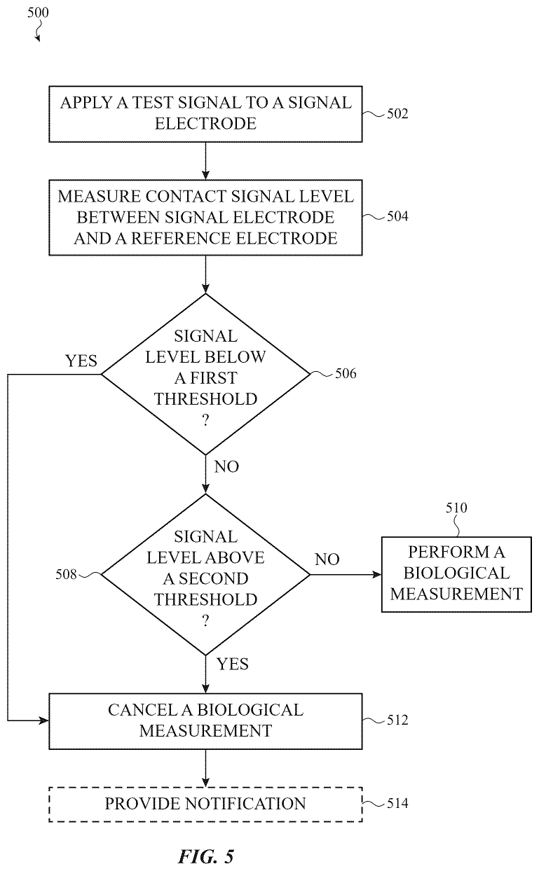

In another example, parasitic leakage 362 and/or 364 may form a conductive pathway between either or both electrodes 114a-114b, respectively, and the housing 202. In some situations, parasitic leakage 362 and/or 364 may form a highly conductive pathway to the housing 202 (e.g., to circuit ground 328), which may significantly affect the amplitude of the contact signal 346. Specifically, the presence of parasitic leakage 362 and/or 364 may significantly reduce the overall impedance between node Vx and circuit ground 328, which may significantly reduce the amplitude of the contact signal 346. This reduced amplitude may indicate an unacceptable level of parasitic leakage, and, as described herein with respect to FIGS. 4 and 5, a biological signal measurement may be canceled accordingly.

In some embodiments, test signal 342 may be applied to the electrodes 114c-114d through a set of respective coupling impedances (e.g., one coupling impedance for each of the electrodes 114c and 114d, respectively). In other embodiments, the test signal 342 may be applied to electrodes 114a, 114c, and 114d through a single, shared coupling impedance, such as coupling impedance 344. In still other embodiments that smartwatch 200 may include a type of electrical switch, such as a multiplexer, that applies test signal 342 to each of the electrodes 114a, 114c, and 114d in succession (through one or more coupling impedances), during a set of corresponding sampling windows.

In addition, each of the electrodes 114c and 114d may include a corresponding circuitry configured as depicted in FIG. 3 for electrode 114a. For example, electrodes 114c and 114d may each include passive components, an amplifier, and an ADC that may each be similar to the corresponding components depicted in FIG. 3 for electrode 114a (e.g., similar to passive components 322-324, amplifier 330, and ADC 332). In some embodiments, the electrodes may share common portions of the circuit. For instance, the smartwatch 200 may include a single amplifier 330 and/or a single ADC 332 that are shared between electrodes 114a, 114c, and 114d. The smartwatch 200 may include one or more electrical switches (e.g., one or more multiplexers) that connect each electrode (and corresponding passive components) to the shared amplifier 330 and/or shared ADC 332, such as during a sampling window in which the test signal (e.g., test signal 342) is applied. Digital output samples 334 produced by ADC 332 (or by a corresponding ADC associated with each electrode 114a, 114c, and 114d) are provided to additional processing circuitry for further analysis, as described herein with respect to the methods of FIGS. 4 and 5.

In some embodiments, the additional processing circuitry may include components associated with signal demodulation, or the processing circuitry may apply a type of demodulation algorithm to the output samples 334. For instance, the processing circuitry may apply signal demodulation to the output samples in order to separate signal components associated with the contact signal from signal components associated with the biological signal, noise, and/or other signal components. Accordingly, the processing circuitry may analyze samples of the contact signal, with other types of signal components removed.

FIG. 4 depicts an example method 400 for determining whether to perform a biological signal measurement based on a contact signal level. The steps of method 400 may be stored as instructions on a non-transitory computer-readable storage device (e.g., memory 104), such that one or more processors (e.g., processor(s) 102) operatively coupled to the memory may utilize these instructions to perform the various steps of the processes described herein. The electrodes, processor(s), memory, and/or other elements associated with method 400 may be part of an electronic device (e.g., device 100, 200).

Method 400 may be performed during a biological signal measurement, or may precede a biological signal measurement, as described herein. In embodiments where method 400 is performed prior to initiating a biological measurement, the biological signal measurement may not commence unless the method has been performed within a threshold amount of time before commencement of the biological signal measurement. For instance, a biological signal measurement may be initiated when an electronic device as described herein receives a measurement request. The measurement request may be received under some predetermined conditions (e.g., a software application running on the device may, with appropriate user permissions, automatically request that the device initiate the biological signal measurement when certain criteria are met) or when a user gives a command to initiate the biological signal measurement, such as by interacting with a control on a user interface, pressing a designated button on the electronic device, giving a voice command, or the like.

In other instances, method 400 may be performed on a periodic basis, which may not be associated with a measurement request. For example, method 400 may be performed during normal use or wear of the device. Measurements and/or other values derived as described herein may be acquired as part of method 400 and stored for later use, such as when a measurement request is received.

Additionally or alternatively, method 400 may be performed during the biological signal measurement. In these instances, the method may be used to determine whether to continue or terminate the biological signal measurement.

At step 402, a test signal is applied to a signal electrode (e.g., at least electrode 114a). The test signal may be any of a range of signals suitable for determining the level of parasitic leakage. The test signal may be configured in any manner as described herein with respect to the test signal 342 of FIG. 3. For example, in some variations the test signal may be a sinusoidal signal having a signal frequency. In some instances, the test signal is generated using a signal generator (e.g., the signal generator 340 of the processing circuitry 300 of FIG. 3).

The test signal may be applied to the signal electrode via a coupling impedance (e.g., coupling impedance 344), as described herein. The coupling impedance, in combination with a user impedance (e.g., user impedance 350) and the impedance of any other passive components (e.g., passive components 322-326) and/or active components (e.g., amplifier 330) that may be present, generates a contact signal (e.g., contact signal 342) that may be part of an input signal to the processing circuitry.

At step 404, the contact signal level is measured while the test signal is applied. The contact signal level may be the amplitude of the contact signal, as measured between a signal electrode and reference electrode (e.g., 114b). The contact signal may be part of an input signal that may include a combination of the contact signal, one or more biological signals, noise and/or measurement artifact, and/or other signals. The measurement may include applying a gain to the input signal (e.g., via amplifier 330), filtering the input signal, digitizing the input signal (e.g., via ADC 332) to generate digital output samples (e.g., output samples 334), and/or performing other measurement operations. The output samples may be further processed to separate the contact signal from other signal components, such as from the one or more biological signals and/or other signal components. In one variation, the contact signal may be separated from other components of the input signal using a demodulation technique, such as IQ demodulation. The separated contact signal may then be analyzed to determine the contact signal level.

At step 406, the determined contact signal level is compared to a first threshold. The first threshold may be provided by the device manufacturer, and may be determined based on user data, calibration and/or other measurement data, heuristics, and/or other types of data. The first threshold may be stored in a memory component of the device (e.g., memory 104).

In some instances, step 406 may be performed on a sample-by-sample basis, where each sample of the contact signal is compared to the first threshold. The contact signal level may be determined to be below the first threshold if the value of any individual sample is less than the first threshold. In other instances, step 406 may include performing a count of the number of samples of the contact signal in which the contact sample level is less than the first threshold. For example, the contact signal level may be determined to be below the first threshold if a predetermined number of samples is below the first threshold. In some examples, the predetermined number of samples may or may not include contiguous samples.

In still other instances, step 406 may include determining an average contact signal level, such as by performing an average of a predetermined number of contact signal samples. In some variations, the average may be a type of moving average taken over a predetermined number of samples of the contact signal. In other variations, other types of averaging may be applied to the contact signal samples. In still other instances, other types of processing may be applied to the contact signal samples as part of determining whether the contact signal level is below the first threshold.

In situations where the contact signal level is determined not to be below the first threshold (e.g., the level of parasitic leakage is acceptable), at step 408, the device may perform the biological signal measurement. In some variations, the biological signal measurement may commence immediately or shortly after the determination that the contact signal level is above the first threshold. In other variations, the device may determine that the contact signal level is above the first threshold prior to commencement of the biological signal measurement, and may continue to measure the contact signal level throughout the measurement (such as when the device is configured to continually determine electrode parasitic leakage during a biological signal measurement). Accordingly, when the device determines that the contact signal level is above the first threshold, the device may allow the current biological signal measurement (e.g., a biological signal measurement already in progress) to continue.

In situations where the contact signal level is determined to be below the first threshold (e.g., the level of parasitic leakage is not acceptable), at step 410, the device may cancel the biological signal measurement. In some variations, cancelling the biological signal measurement includes foregoing commencement of the biological signal measurement, when the contact signal level is determined to be below the first threshold. In other variations, cancelling the biological signal measurement includes terminating the performance of the biological signal measurement, such as when method 400 is performed during the biological signal measurement. For instance, the device may initially determine that the contact signal level is above the first threshold and commence the biological signal measurement (e.g., at step 408). The device may be configured to subsequently perform method 400 during the biological signal measurement, and may subsequently detect that the contact signal level is below the first threshold (e.g., when parasitic leakage occurs during the biological signal measurement). The device may terminate the biological signal measurement in such a circumstance, at step 410.

In some embodiments, when the biological signal measurement is cancelled, at step 412, a notification may be provided to the user. For example, the device may provide a text and/or graphical notification to the user describing the cause of the cancelled biological signal measurement. The notification may be provided via a user interface of the device (e.g., user interface 110). For instance, in some embodiments, the notification may be provided to a display of the device, or on the display of another device (e.g., a smartphone connected to the device). In some cases, the notification may direct the user to clean the device or portions of the device, so as to remove extraneous materials from surfaces of the device. For example, the notification may direct the user to clean one or more of the electrodes, portions of the device housing (e.g., conductive region 212a and/or non-conductive portion 212b), and/or other portions of the device (e.g., input devices 208 and/or 210). Additionally or alternatively, the notification may be provided via audible alert (e.g., an alarm or other alert) and/or haptic feedback.

As described herein, method 400 may be performed by a device for any of the signal electrodes included therein. For example, the test signal may be applied to one or more signal electrodes designed to contact a finger or another part of the body of the user (e.g., electrodes 114c-114d), in addition to a signal electrode designed to contact the wrist (e.g., electrode 114a). The resulting contact signal for these additional signal electrodes may be analyzed as described for method 400, and the corresponding contact signal level(s) used to determine whether the biological signal measurement should be performed or cancelled.

FIG. 5 depicts another example method for determining whether to perform a biological signal measurement based on a determined contact signal level. The steps of method 500 may be stored as instructions on a non-transitory computer-readable storage device (e.g., memory 104), such that one or more processors (e.g., processor(s) 102) operatively coupled to the memory may utilize these instructions to perform the various steps of the processes described herein. The electrodes, processor(s), memory, and/or other elements associated with method 500 may be part of an electronic device (e.g., device 100, 200). Method 500 may be performed during a biological signal measurement, or may precede a biological signal measurement, such as described with respect to method 400.

At step 502, a test signal is applied to a signal electrode (e.g., at least electrode 114a). At step 504, the contact signal level between the signal electrode and a reference electrode is measured. At step 506, the contact signal level is compared to a first threshold. Each of the steps of steps 502-506 may be performed in any suitable manner as described with respect to steps 402-406, respectively, of method 400 of FIG. 4.

If the contact signal level is determined to be below the first threshold, the biological signal measurement is canceled at step 512. In some embodiments, a notification may be provided at step 514. Each of the steps of steps 512-514 may be performed in any suitable manner as described with respect to steps 410-412, respectively, of method 400.

If the contact signal level is determined to be above the first threshold (e.g., the signal level is not below the first threshold), the contact signal level is compared to a second threshold, at step 508. The second threshold represents a level of electrode-skin contact, above which the user is considered to be making insufficient contact with one or more of the electrodes. For example, a high signal level may represent high electrode-skin impedance, such as when the user is making poor contact with one or more electrodes (e.g., insufficient surface area of contact) or is not making any contact with one or more of the electrodes.

If the contact signal level is determined to not be above the second threshold (e.g., the user is making sufficient contact with one or more of the electrodes), a biological signal measurement is performed at step 510. Each of the operations of step 510 may be performed in any suitable manner as described with respect to step 408 of method 400. If the contact signal level is determined to be above the second threshold (e.g., the user is not making sufficient contact with one or more of the electrodes), the biological signal measurement is canceled at step 512.

As described herein, method 500 may be performed by a device for any of the signal electrodes included therein. For example, the test signal may be applied to one or more signal electrodes designed to contact a finger or another part of the body of the user (e.g., electrodes 114c-114d), in addition to a signal electrode designed to contact the wrist (e.g., electrode 114a). The resulting contact signal for these other signal electrodes may be analyzed as described for method 500, and the corresponding contact signal level(s) used to determine whether the biological signal measurement should be performed or cancelled.

Embodiments contemplated herein include one or more non-transitory computer-readable media storing instructions to cause an electronic device, upon execution of the instructions by one or more processors of the electronic device, to perform one or more elements of the method 400 or 500. In the context of the method 400 or 500, this non-transitory computer-readable media may be, for example, a memory (e.g., a memory 104, as described herein) of a device (e.g., device 100).

The present disclosure contemplates that the entities responsible for the collection, analysis, disclosure, transfer, storage, or other use of such personal information data will comply with well-established privacy policies and/or privacy practices. In particular, such entities should implement and consistently use privacy policies and practices that are generally recognized as meeting or exceeding industry or governmental requirements for maintaining personal information data private and secure. Such policies should be easily accessible by users, and should be updated as the collection and/or use of data changes. Personal information from users should be collected for legitimate and reasonable uses of the entity and not shared or sold outside of those legitimate uses. Further, such collection/sharing should occur after receiving the informed consent of the users. Additionally, such entities should consider taking any needed steps for safeguarding and securing access to such personal information data and ensuring that others with access to the personal information data adhere to their privacy policies and procedures. Further, such entities can subject themselves to evaluation by third parties to certify their adherence to widely accepted privacy policies and practices. In addition, policies and practices should be adapted for the particular types of personal information data being collected and/or accessed and adapted to applicable laws and standards, including jurisdiction-specific considerations. For instance, in the US, collection of or access to certain health data may be governed by federal and/or state laws, such as the Health Insurance Portability and Accountability Act (“HIPAA”); whereas health data in other countries may be subject to other regulations and policies and should be handled accordingly. Hence different privacy practices should be maintained for different personal data types in each country.

Despite the foregoing, the present disclosure also contemplates embodiments in which users selectively block the use of, or access to, personal information data. That is, the present disclosure contemplates that hardware and/or software elements can be provided to prevent or block access to such personal information data. For example, in the case of determining a metric, the present technology can be configured to allow users to select to “opt in” or “opt out” of participation in the collection of personal information data during registration for services or anytime thereafter. In addition to providing “opt in” and “opt out” options, the present disclosure contemplates providing notifications relating to the access or use of personal information. For instance, a user may be notified upon downloading an app that their personal information data will be accessed and then reminded again just before personal information data is accessed by the app.

Moreover, it is the intent of the present disclosure that personal information data should be managed and handled in a way to minimize risks of unintentional or unauthorized access or use. Risk can be minimized by limiting the collection of data and deleting data once it is no longer needed. In addition, and when applicable, including in certain health related applications, data de-identification can be used to protect a user's privacy. De-identification may be facilitated, when appropriate, by removing specific identifiers (e.g., date of birth, etc.), controlling the amount or specificity of data stored (e.g., collecting location data at a city level rather than at an address level), controlling how data is stored (e.g., aggregating data across users), and/or other methods.

Therefore, although the present disclosure broadly covers use of personal information data to implement one or more various disclosed embodiments, the present disclosure also contemplates that the various embodiments can also be implemented without the need for accessing such personal information data. That is, the various embodiments of the present technology are not rendered inoperable due to the lack of all or a portion of such personal information data. For example, the output result may be provided based on non-personal information data or a bare minimum amount of personal information, such as events or states at the device associated with a user, other non-personal information, or publicly available information.

The foregoing description, for purposes of explanation, used specific nomenclature to provide a thorough understanding of the described embodiments. However, it will be apparent to one skilled in the art that the specific details are not required in order to practice the described embodiments. Thus, the foregoing descriptions of the specific embodiments described herein are presented for purposes of illustration and description. They are not targeted to be exhaustive or to limit the embodiments to the precise forms disclosed. It will be apparent to one of ordinary skill in the art that many modifications and variations are possible in view of the above teachings.

What is claimed is:

1. A device, comprising:
a signal electrode;
a reference electrode;
a signal generator configured to apply a test signal to the signal electrode; and
processing circuitry configured to perform a biological signal measurement using the signal electrode and reference electrode, wherein the processing circuitry is further configured to:
measure a contact signal associated with the biological signal measurement, wherein a contact signal level of the contact signal is measured between the signal electrode and reference electrode while the test signal is applied to the signal electrode;
compare the contact signal level to a first threshold; and
cancel the biological signal measurement when the contact signal level is determined to be below the first threshold.

2. The device of claim 1, wherein the processing circuitry is further configured to:
upon determining that the contact signal level is below the first threshold, provide a notification to a user.

3. The device of claim 1, wherein canceling the biological signal measurement comprises forgoing commencement of the biological signal measurement.

4. The device of claim 1, wherein the processing circuitry is further configured to:
compare the contact signal level to a second threshold, wherein the second threshold is larger than the first threshold; and
cancel the biological signal measurement when the contact signal level is determined to be above the second threshold.

5. The device of claim 1, comprising a housing, wherein the signal electrode and reference electrode are positioned on a common side of the housing.

6. The device of claim 1, wherein the processing circuitry is configured to measure the contact signal prior to commencing the biological signal measurement.

7. The device of claim 1, wherein:
the processing circuitry is configured to measure the contact signal during performance of the biological signal measurement; and
canceling the biological signal measurement comprises terminating performance of the biological signal measurement.

8. The device of claim 7, wherein the processing circuitry is configured to measure the contact signal continuously during performance of the biological signal measurement.

9. A method for detecting electrode parasitic leakage, comprising:
applying a test signal to a signal electrode;
measuring a contact signal associated with a biological signal measurement, wherein the contact signal level of the contact signal is measured between the signal electrode and a reference electrode while the test signal is applied to the signal electrode;
determining that the contact signal level is below a first threshold; and
canceling the biological signal measurement in response to determining that the contact signal level is below the first threshold.

10. The method of claim 9, further comprising:
providing a notification to a user in response to determining that the contact signal level is below the first threshold.

11. The method of claim 9, wherein canceling the biological signal measurement comprises forgoing commencement of the biological signal measurement.

12. The method of claim 9, wherein:
measuring the contact signal comprises measuring the contact signal during performance of the biological signal measurement; and
canceling the biological signal measurement comprises terminating performance of the biological signal measurement.

13. The method of claim 9, wherein the method further comprises:
performing an additional measurement of the contact signal associated with a subsequent biological signal measurement;
determining that a corresponding contact signal level of the additionally measured contact signal is above a second threshold, wherein the second threshold is larger than the first threshold; and
canceling the subsequent biological signal in response to determining that the contact signal level of the additionally measured contact signal is above the second threshold.

14. The method of claim 9, wherein the test signal is applied to the signal electrode while the signal electrode is positioned in contact with a wrist of a user.

15. The method of claim 9, wherein determining that the contact signal level is below the first threshold includes calculating an average contact signal level and comparing the calculated average contact signal level to the first threshold.

16. A method, comprising:
applying a test signal to a signal electrode;
measuring a contact signal associated with the signal electrode and a reference electrode while the test signal is applied to the signal electrode;
determining that a signal level of the contact signal is below a first threshold; and
providing a notification to a user in response to determining that the signal level of the contact signal is below the first threshold.

17. The method of claim 16, comprising:
canceling a biological signal measurement in response to determining that the signal level of the contact signal is below the first threshold.

18. The method of claim 17, wherein:
measuring the contact signal comprises measuring the contact signal during performance of the biological signal measurement.

19. The method of claim 16, wherein the test signal is sinusoidal.

20. The method of claim 16, wherein determining that the contact signal level is below the first threshold includes calculating an average contact signal level and comparing the calculated average contact signal level to the first threshold.
